(19) United States
(12) Patent Application Publication
(10) Pub. No.: US 2022/0068652 A1
(43) Pub. Date: Mar. 3, 2022

(54) PLASMA ETCHING METHOD, AND PRODUCTION METHOD FOR SEMICONDUCTOR ELEMENT

(71) Applicant: Panasonic Intellectual Property Management Co., Ltd., Osaka (JP)

(72) Inventor: Yoshimasa INAMOTO, KYOTO (JP)

(21) Appl. No.: 17/406,801

(22) Filed: Aug. 19, 2021

(30) Foreign Application Priority Data
Sep. 3, 2020 (JP) 2020-148256

(51) Int. Cl. H01L 21/3065; H01L 21/311

(52) U.S. Cl. CPC H01L 21/3065; H01L 21/31144; H01L 21/31116

(57) ABSTRACT

Disclosed is a plasma etching method for a substrate that enables formation of various forward-tapered shapes. The plasma etching method disclosed includes the steps of: (i) placing, in a chamber, a substrate 10 including a compound semiconductor layer 11 formed of a Group III-V compound semiconductor, and a resist mask 12 disposed on one principal surface 11a of the compound semiconductor layer 11; and (ii) plasma etching the compound semiconductor layer 11 and the resist mask 12 by exposing the compound semiconductor layer 11 and the resist mask 12 to a plasma, thereby forming a slope 11s that forms a forward-tapered shape on the compound semiconductor layer 11. The Group III-V compound semiconductor includes Ga and As. The plasma etching in the step (ii) is performed using, as an etching gas, a gas mixture including nitrogen gas and a gas containing chlorine.

### CROSS REFERENCE TO RELATED APPLICATION

The present application is based on and claims priority under 35 U.S.C. § 119 with respect to the Japanese Patent Application No. 2020-148256 filed on Sep. 3, 2020, of which entire content is incorporated herein by reference into the present application.

### TECHNICAL FIELD

The present invention relates to an etching method for a substrate, and a production method for a semiconductor element.

### BACKGROUND

Conventionally, semiconductor elements using a substrate made of a GaAs compound semiconductor have been formed. In the production process of the semiconductor elements, a step of etching the GaAs compound semiconductor is performed.

Japanese Laid-Open Patent Publication No. 2002-151466 discloses “A dry etching method for etching a compound substrate including gallium and arsenic using an etching gas including chlorine and boron trichloride, wherein an inert gas is added to the etching gas”. In Japanese Laid-Open Patent Publication No. 2002-151466, argon gas is disclosed as the inert gas.

As disclosed in Japanese Laid-Open Patent Publication No. 2002-151466, an etching gas containing chlorine has hitherto been used as an etching for a GaAs compound semiconductor substrate. The use of the etching gas containing chlorine increases the etching rate of the GaAs compound semiconductor substrate.

### SUMMARY

In the production of semiconductor elements using a GaAs compound semiconductor substrate, the GaAs compound semiconductor substrate has been conventionally etched so as to have a forward-tapered shape. However, with the conventional methods, it has been difficult to significantly change the inclination of a side surface of the forward-tapered shape. In particular, it has been difficult to form a forward-tapered shape having a side surface with a small gradient. Under such circumstances, an object of the present disclosure is to provide a plasma etching method for a substrate and a production method for a semiconductor element that enable formation of various forward-tapered shapes.

One aspect of the present disclosure relates to a plasma etching method for a compound semiconductor layer formed of a Group III-V compound semiconductor. This plasma etching method includes the steps of: (i) placing, in a chamber, a substrate including the compound semiconductor layer and a resist mask that is disposed on one principal surface of the compound semiconductor layer and has an opening; and (ii) plasma etching the compound semiconductor layer and the resist mask by exposing the compound semiconductor layer and the resist mask to a plasma in the chamber, thereby forming a that forms a forward-tapered shape on the compound semiconductor layer, wherein the Group III-V compound semiconductor includes Ga and As, and the plasma etching in the step (ii) is performed using, as an etching gas, a gas mixture including nitrogen gas and a gas containing chlorine.

Another aspect of the present disclosure relates to a production method for a semiconductor element including a compound semiconductor layer formed of a Group III-V compound semiconductor. This production method includes the steps of: (i) placing, in a chamber, a substrate including the compound semiconductor layer and a resist mask that is disposed on one principal surface of the compound semiconductor layer and has an opening; and (ii) plasma etching the compound semiconductor layer and the resist mask by exposing the compound semiconductor layer and the resist mask to a plasma in the chamber, thereby forming a slope that forms a forward-tapered shape on the compound semiconductor layer, wherein the Group III-V compound semiconductor includes Ga and As, and the plasma etching in the step (ii) is performed using, as an etching gas, a gas mixture including nitrogen gas and a gas containing chlorine.

According to the present disclosure, it is possible to form various forward-tapered shapes on a substrate including a compound semiconductor layer formed of a compound of a Group III element, including Ga, and As.

### BRIEF DESCRIPTION OF THE DRAWINGS

FIG. 1A is a diagram schematically showing a step of a plasma etching method according to Embodiment 1.

FIG. 1B is a diagram schematically showing a step following the step of FIG. 1A.

FIG. 2 is a diagram schematically showing an example of an apparatus used for the plasma etching method according to Embodiment 1.

FIG. 3 is a schematic diagram for illustrating an example of plasma etching in the case of an etching selectivity of Vs/Vr=1.

FIG. 4 is a schematic diagram for illustrating an example of plasma etching in the case of an etching selectivity of Vs/Vr>1.

FIG. 5 is a schematic diagram for illustrating an example of plasma etching in the case of an etching selectivity of Vs/Vr<1.

FIG. 6 is a graph showing an example of the results obtained by performing an experiment for a plasma etching method of the present disclosure.

FIG. 7 is a graph showing the etching selectivities corresponding to the results shown in FIG. 6.

FIG. 8 is a graph showing a relationship between the gas flow rate ratio and the gradient of a slope, obtained in the experiment shown in FIG. 6.

FIG. 9 is a graph showing another example of the results obtained by performing an experiment for the plasma etching method of the present disclosure.

FIG. 10 is a graph showing the etching selectivities corresponding to the results shown in FIG. 9.

FIG. 11 is a graph showing a relationship between the gas flow rate ratio and the gradient of a slope, obtained in the experiment shown in FIG. 9.

FIG. 12 is a graph showing another example of the results obtained by performing an experiment for the plasma etching method of the present disclosure.

FIG. 13 is a graph showing the etching selectivities corresponding to the results shown in FIG. 12.

### DETAILED DESCRIPTION

In the following, embodiments of the present disclosure will be described by way of examples. However, the present disclosure is not limited to the examples described below. Although examples of specific numerical values and materials may be given in the following description, other numerical values and materials may be used as long as the effects of the present disclosure can be achieved. As used herein, in the expression “the range of a numerical value A to a numerical value B”, this range includes the numerical value A and the numerical value B.

### (Plasma Etching Method)

The plasma etching method of the present disclosure is a plasma etching method for a compound semiconductor layer formed of a Group III-V compound semiconductor, and includes steps (i) and (ii). This plasma etching method may be hereinafter referred to as an “etching method (EM)”. The aforementioned compound semiconductor layer may be hereinafter referred to as a “compound semiconductor layer (L)”.

The step (i) is a step of placing, in a chamber, a substrate including a compound semiconductor layer (L), and a resist mask that is disposed on one principal surface of the compound semiconductor layer (L) and has an opening. The chamber is a chamber into which an etching gas is introduced to generate a plasma.

The step (ii) is a step of plasma etching the compound semiconductor layer (L) and the resist mask by exposing the compound semiconductor layer (L) and the resist mask to a plasma in the chamber, thereby forming a slope that forms a forward-tapered shape on the compound semiconductor layer (L). The forward-tapered shape may be formed by only one slope. In another aspect, the step (ii) is a step of forming a slope having a gradient α(s) of less than 90° on the compound semiconductor layer (L) by the above-described plasma etching.

The Group III-V compound semiconductor that forms the compound semiconductor layer (L) includes Ga (gallium) and As (arsenic). The Group III-V compound semiconductor may include a trace amount of an impurity (dopant) in addition to a Group III element (Group 13 element) and a Group V element (Group 15 element).

The Group III element that forms the Group III-V compound semiconductor includes at least Ga, and may further include at least one selected from the group consisting of Al (aluminum) and In (indium). The Group V element that forms the Group III-V compound semiconductor includes at least arsenic (As), and may further include phosphorus (P). Examples of the compound semiconductor layer (L) include GaAs. A part of Ga may be replaced by Al and/or In, and a part of As may be replaced by P and/or nitrogen (N).

Although the Group V element that forms the Group III-V compound semiconductor may include nitrogen (N), the Group V element typically does not include nitrogen (N), or includes a trace amount of nitrogen if it does. The proportion of nitrogen in the Group V element may be in the range of 0 to 100 atom %, and typically in the range of 0 to 30 atom % (e.g., the range of 0 to 20 atom %, 0 to 10 atom %, or 0 to 5 atom %). In the plasma etching method of the present disclosure, the etching gas includes N₂, and Ga in the compound semiconductor layer (L) reacts with N₂ in the etching gas, to generate GaN, thereby reducing the etching rate. When the Group V element includes a large amount of nitrogen, Ga in the compound semiconductor layer (L) is less likely to react with the gas (etching gas) containing chlorine. As a result, the etching rate is excessively reduced, so that the etching process is likely to become unstable. Therefore, when the compound semiconductor layer (L) includes a certain amount of nitrogen, it may be difficult to increase the ratio of the N₂ gas to the etching gas than when the compound semiconductor layer (L) is GaAs. That is, when the compound semiconductor layer (L) includes a certain amount of nitrogen, the etching process may become unstable if the ratio of the N₂ gas to the etching gas is increased in order to form a side surface having a forward-tapered shape. For this reason, the effects achieved by the method of the present disclosure may be reduced when the Group V element in the compound semiconductor layer (L) includes a large amount of nitrogen. In other words, the method of the present disclosure is preferably used for a compound semiconductor layer (L) having a small proportion of nitrogen in the Group V element. For example, the method of the present disclosure can be preferably used for a compound semiconductor layer (L) having a proportion of nitrogen in the Group V element in the range of 0 to 30 atom % (e.g., the range of 0 to 10 atom % or the range of 0 to 5 atom %), and can be particularly preferably used for a compound semiconductor layer (L) that does not include nitrogen.

The plasma etching in the step (ii) is performed using, as an etching gas, a gas mixture including nitrogen gas and a gas containing chlorine (chlorine-containing gas). The etching gas is a gas introduced into a chamber at the time of plasma etching. A plasma is generated by charging energy to the etching gas.

### (Production Method for Semiconductor Element)

The production method of the present disclosure is a production method for a semiconductor element including a compound semiconductor layer (L) formed of a Group III-V compound semiconductor. This production method may be hereinafter referred to as a “production method (PM)”. The production method (PM) includes the same steps as those of the etching method (EM). Therefore, the matters described for the etching method (EM) can be applied to the production method (PM), and the matters described for the production method (PM) can be applied to the etching method (EM). Thus, redundant descriptions may be omitted.

The production method (PM) includes the above-described steps (i) and (ii). Similarly to the etching method (EM), the plasma etching in the step (ii) of the production method (PM) is performed using, as an etching gas, a gas mixture including nitrogen gas and a gas containing chlorine.

In the production method (PM), a semiconductor element is produced using a substrate including the compound semiconductor layer (L). In the production process, the compound semiconductor layer (L) is etched.

There is no particular limitation on the semiconductor element produced by the production method (PM). The production method (PM) can be applied to any semiconductor element that includes the compound semiconductor layer (L). Examples of the semiconductor element produced by the production method (PM) include a transistor such as a HEMT and a MESFET, and a semiconductor laser.

In the etching method (EM) and the production method (PM), the compound semiconductor layer (L) and the resist mask are etched together in the step (ii). The plasma etching in the step (ii) is performed using, as an etching gas, a gas mixture including nitrogen gas and a chlorine-containing gas. The use of such a gas mixture makes it possible to reduce the value of Vs/Vr (etching selectivity), which is the ratio between an etching rate Vs of the compound semiconductor layer and an etching rate Vr of the resist mask. By etching the semiconductor layer (L) and the resist mask together under a condition with a small value of Vs/Vr, it is possible to further reduce the gradient α(s) of the slope that forms the forward-tapered shape. Therefore, according to the method of the present disclosure, it is possible to form various forward-tapered shapes. The method of the present disclosure is particularly preferably used when it is necessary to form a shape having a slope with an acute gradient α(s) (e.g., a forward-tapered shape) on the compound semiconductor layer (L).

### (Matters Common to Etching Method (EM) and Production Method (PM))

The substrate used for the method of the present disclosure may include a layer other than the compound semiconductor layer (L) and the resist mask. In the case of producing a semiconductor element, the substrate may include a layer required to form the semiconductor element. Of course, at least a part of the layer other than the compound semiconductor layer (L) may be formed after the step (ii) is completed. The layer other than the compound semiconductor layer (L) is selected according to the type of the semiconductor element to be formed. After completion of the step (ii), the resist mask may be removed as needed.

As the resist mask, a mask that is etched by the plasma etching in the step (ii) is used. A known resin mask may be used as the resist mask. Examples of the resin mask include a photoresist mask. Examples of the material of the resin resist mask include a Novolak resin.

The opening of the resist mask is formed in a portion where the compound semiconductor layer (L) is to be etched. Through the opening of the resist mask, the compound semiconductor layer (L) is etched. By etching the resist mask, the opening is widened, and the compound semiconductor layer (L) is etched also through the widened opening.

In the plasma etching in the step (ii), usually, etching (anisotropic etching) is performed by applying a bias voltage to the generated plasma. The high-frequency power applied for generating the plasma and the bias voltage can be each selected as appropriate from a suitable range.

The gas used for generation of the plasma, that is, the gas that is introduced into the chamber in which a plasma is generated, includes nitrogen gas (N₂) and a chlorine-containing gas, as described above. The etching selectivity (Vs/Vr) can be changed by changing the flow rate ratio between the chlorine-containing gas and the nitrogen gas. As a result, it is possible to change the gradient α(s) of the slope that forms the forward-tapered shape.

There is no particular limitation on the apparatus for performing the etching method (EM) and the production method (PM), and the methods can be performed using a known plasma etching apparatus. For example, an inductively coupled plasma etching apparatus (ICP etching apparatus) or the like may be used.

The gas containing chlorine (chlorine-containing gas) may include at least one gas selected from the group consisting of BCl₃ (boron trichloride gas) and Cl₂ (chlorine gas). The chlorine-containing gas may include, for example, only a chlorine gas, or only a boron trichloride gas, or may be a gas mixture thereof.

In the step (ii), the volume ratio of the gases constituting the gas mixture may be controlled such that the value of Vs/Vr, which is the ratio between the etching rate Vs of the compound semiconductor layer and the etching rate Vr of the resist mask, is less than 1. Specifically, the ratio between the gas containing chlorine and the nitrogen gas may be controlled such that the value of Vs/Vr is less than 1. With these configurations, it is possible to reduce the gradient α(s) of the slope that forms the forward-tapered shape. The value of Vs/Vr may be greater than or equal to 0.1 and less than 1 (e.g., in the range of 0.3 to 0.9 or the range of 0.3 to 0.6).

The proportion (volume ratio) of the chlorine-containing gas in the entire etching gas may be in the range of 2 to 20% (e.g., the range of 3 to 5%). The value of Vs/Vr can be reduced by reducing the proportion of the chlorine-containing gas.

The gradient α(s) of the slope formed on the compound semiconductor layer (L) by the step (ii) may be controlled by controlling the volume ratio of the gases constituting the gas mixture.

On the substrate in the step (i), the angle (gradient α(r)) formed between the one principal surface of the compound semiconductor layer and a side surface of the resist mask may be in the range of 10° to 90°. This angle (gradient α(r)) may be in the range of 10° to 45°. By reducing this angle, it is possible to further reduce the gradient of the slope formed on the compound semiconductor layer (L).

The volume ratio of the gases constituting the above-described gas mixture may be controlled such that the gradient α(s) of the slope formed on the compound semiconductor layer (L) by the step (ii) is 60° or less, 45° or less, 30° or less, or 12° or less. For example, by reducing the proportion of the chlorine-containing gas in the gas mixture, it is possible to reduce the value of Vs/Vr (etching selectivity). As a result, it is possible to reduce the gradient of the slope.

The above-described gas mixture may include Ar gas. The inclusion of Ar gas in the gas mixture enhances the ion sputtering properties. As a result, a layer (e.g., an oxide layer) that is present on the surface of the compound semiconductor layer (L) and is difficult to etch can be removed, or any redeposition of a reaction product of nitrogen or carbon can be efficiently removed. Accordingly, the inclusion of Ar gas in the gas mixture may facilitate smoothing of a side wall surface of the compound semiconductor layer (L).

In the following, exemplary embodiments of the present disclosure will be described in detail with reference to the drawings. The method described below can be modified based on the above descriptions. The matters described below may be applied to the above-described embodiment. In the embodiments described below, matters that are not essential to the method of the present disclosure may be omitted.

### Embodiment 1

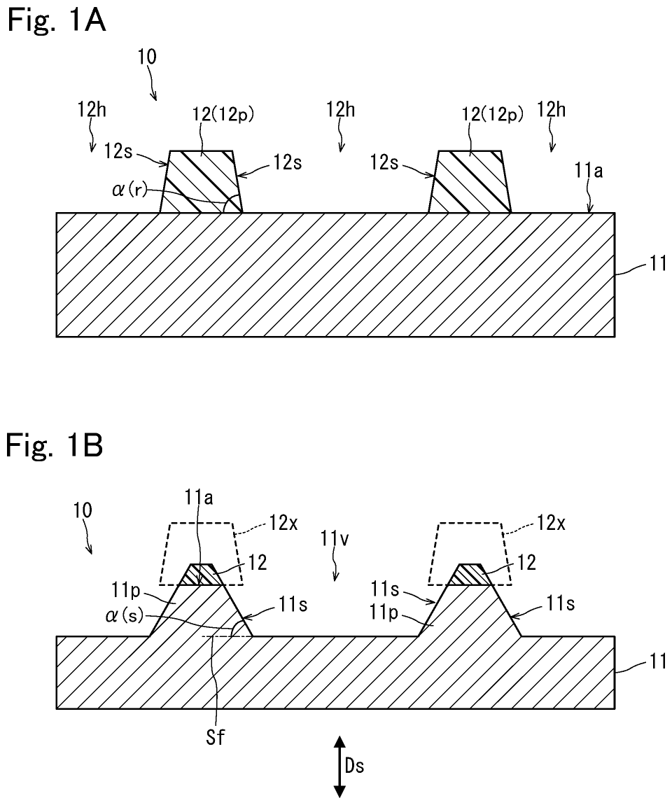

In Embodiment 1, an example of the plasma etching method (EM) will be described. First, as shown in FIG. 1A, a substrate 10 including a compound semiconductor layer 11, and a resist mask (resist pattern) 12 disposed on one principal surface 11a of the compound semiconductor layer 11 is prepared. The compound semiconductor layer 11 is the above-described compound semiconductor layer (L). The compound semiconductor layer 11 may be a compound semiconductor substrate. That is, the substrate 10 may include a compound semiconductor substrate, and the resist mask 12 formed on one principal surface thereof. Alternatively, the substrate 10 may include a layer other than the compound semiconductor layer 11.

The resist mask 12 has openings 12h (through holes) formed therein. Through the openings 12h, the compound semiconductor layer 11 is exposed. The resist mask 12 can be formed by a known method. For example, first, a resist film is formed on the one principal surface 11a by spin coating or the like. Next, the resist film is patterned by a photolithography/etching process or the like. In this manner, a resist mask 12 having predetermined openings 12h can be formed.

The thickness of the resist mask 12 may be selected according to the etching rate Vs of the compound semiconductor layer 11, the etching rate Vr of the resist mask 12, the shape to be formed by etching (the shape of the compound semiconductor layer 11), and so forth. Usually, the thickness of the resist mask 12 is selected such that a part of the resist mask 12 remains upon completion of the step (ii). In an example, the thickness of the resist mask 12 may be in the range of 0.4 μm to 1.2 μm. In the case of deeply etching the compound semiconductor layer 11, the thickness of the resist mask 12 may be increased accordingly. For example, the thickness of the resist mask 12 may be greater than 1.2 or may be 2 μm or more.

The resist mask 12 has side surfaces 12s that face the corresponding openings 12h. Each of the side surfaces 12s has an acute gradient α(r) relative to the one principal surface 11a of the compound semiconductor layer 11. Of the resist mask 12, portions 12p, each of which is a portion sandwiched between two side surfaces 12s, has a forward-tapered shape. That is, the resist mask 12 includes portions 12p having a forward-tapered shape. Here, the forward-tapered shape is, for example, a shape that is tapered away from the center of the compound semiconductor layer 11 in the thickness direction. The portions 12p may have the shape of a ridge extending in an elongated manner, or may have the shape of a truncated square pyramid or a truncated cone.

There is no particular limitation on the method for forming the openings 12h having an acute gradient α, and a known method may be used. For example, the openings 12h may be formed by using photolithography and adjusting the expose conditions or the developing conditions. For example, a resist pattern formed by photolithography or the like may be baked, thus making the gradient α(r) more acute.

Conventionally, it has been considered that the gradient of a resist mask formed by photolithography or the like is desirably as small as possible in order to obtain a forward-tapered processed shape. For this reason, the shape of the resist mask has been controlled by baking or the like after forming the resist mask. However, there has been a problem in terms of the stability of the shape control. The method of the present disclosure can control the gradient α(s) by controlling the volume ratio of the gases constituting the etching gas, without significantly depending on the gradient α(r) of the resist mask.

Next, as shown in FIG. 1B, the resist mask 12 and the compound semiconductor layer 11 are etched, thereby forming slopes 11s that form a forward-tapered shape on the compound semiconductor layer 11. The etching of the resist mask 12 and the compound semiconductor layer 11 is performed by exposing the compound semiconductor layer 11 and the resist mask 12 to a plasma. As the etching gas for the plasma etching, the above-described gas mixture is used.

In FIG. 1B, an outer edge 12x of the resist mask 12 before etching is indicated by dotted lines. FIG. 1B shows the gradient α(s) of the slope 11s of the compound semiconductor layer 11. The gradient α(s) is the gradient of the slope 11s relative to a plane Sf perpendicular to a thickness direction Ds of the substrate 10.

The gradient α(s) is less than 90°. The surface of such a slope 11s can be viewed from the one principal surface 11a side. On the other hand, the surface of a slope that forms a reverse-tapered shape cannot be viewed from the one principal surface 11a side.

Of the section removed by the plasma etching, a recess 11v is formed in each of the portions sandwiched between two adjacent slopes 11s. The recess 11v is a recess having an opening whose area increases away from the center of the compound semiconductor layer 11 in the thickness direction.

Of the compound semiconductor layer 11, a portion 11p sandwiched between two slopes 11s have a forward-tapered shape. That is, the compound semiconductor layer 11 includes the portion 11p having a forward-tapered shape. The portion 11p may have the shape of a ridge extending in an elongated manner, or may have the shape of a truncated square pyramid or a truncated cone.

The production method (PM) for a semiconductor element forms the structure of a part of the semiconductor element by etching the compound semiconductor layer (L) using the above-described etching method (EM). The rest of the steps are not particularly limited, and may be performed using a known technique.

### (Plasma Etching Apparatus)

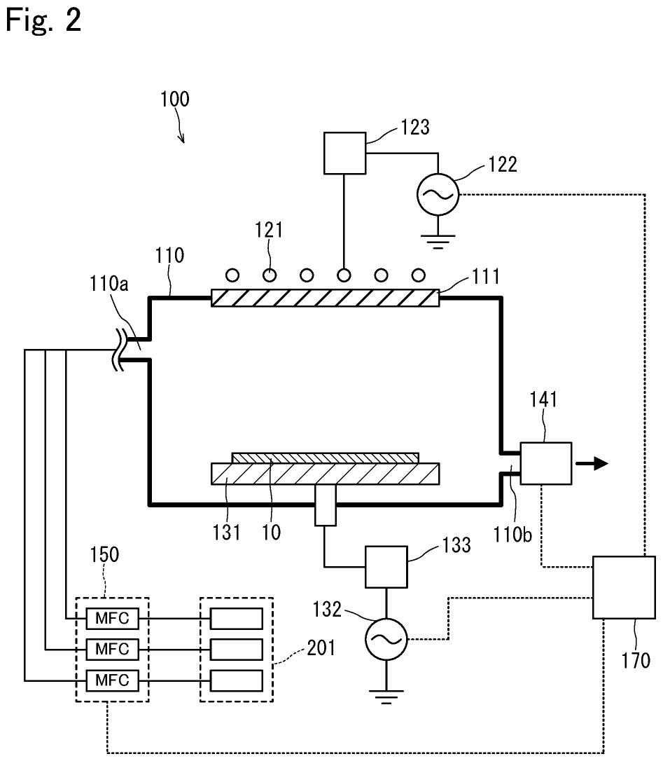

FIG. 2 shows an example of an apparatus used in the plasma etching of the step (ii). The apparatus 100 shown in FIG. 2 includes a chamber 110, upper electrodes (antennas) 121, a first high-frequency power supply 122, a first matching circuit 123, a substrate stage 131, a second high-frequency power supply 132, a second matching circuit 133, a pressure adjustment device 141, a gas flow control portion 150, a control device 170, and a pressure gauge (not shown). The control device 170 is connected to devices that require control, and performs control necessary for plasma etching. FIG. 1 shows only a part of connections between the control device 170 and the devices. Known devices can be used as the devices included in the apparatus 100, and therefore detailed descriptions thereof have been omitted. As long as the method of the present invention can be performed, these devices and the configuration (including the arrangement) thereof can be modified.

The chamber 110 is a chamber whose interior can be maintained under a reduced pressure. The chamber 110 includes a gas introduction port 110a, a gas discharge port 110b, and a dielectric window 111. The dielectric window 111 is made of a dielectric material (e.g., aluminum nitride, alumina, quartz, or the like). The upper electrodes 121 are disposed adjacent to the dielectric window 111.

The substrate 10 to be plasma etched by the apparatus 100 is placed on the substrate stage 131. The substrate stage 131 is connected to the second high-frequency power supply 132, and also functions as a bottom electrode.

The pressure adjustment device 141 is connected to the gas discharge port 110b, and reduces the pressure in the chamber 110. A vacuum pump or the like is used as the pressure adjustment device 141. The pressure adjustment device 141 may include a pressure adjustment valve or the like. The apparatus 100 includes the pressure gauge for monitoring the pressure in the chamber 110. The control device 170 controls the pressure adjustment device 141 based on the output of the pressure gauge, and adjusts the pressure in the chamber 110.

A gas supply source 201 (e.g., a gas cylinder) for the gas supplied into the chamber 110 is connected to the gas flow control portion 150. The control device 170 controls the gas flow control portion 150, and adjusts the flow rate of each of the gases. The gas flow control portion 150 includes a massflow controller (MFC) disposed in the flow path of each of the gases that are supplied. The gases supplied from the gas supply source 201 are introduced into the chamber 110 through the gas flow control portion 150 and the gas introduction port 110a. FIG. 2 shows an example of an apparatus using three types of gases.

The chamber 110 includes a mechanism (e.g., an opening/closing mechanism) (not shown) for transporting the substrate 10 into and out of the chamber 110. In the case of performing plasma etching using the apparatus 100, first, the substrate 10 is placed on the substrate stage 131. Next, the pressure in the chamber 110 is reduced by the pressure adjustment device 141, and predetermined gases are introduced into the chamber 110 from the gas supply source 201. At this time, the pressure in the chamber 110 is adjusted to a desired pressure as described above.

There is no particular limitation on the pressure in the chamber 110 at the time of performing plasma etching, and a pressure suitable for plasma etching may be selected. In an example, the pressure in the chamber 110 may be set in the range of 0.4 Pa to 5 Pa.

The above-described plurality of gases are introduced into the chamber 110. That is, a gas mixture is introduced into the chamber 110. There is no particular limitation on the composition ratio (volume ratio) of the gases constituting the gas mixture, and the composition ratio can be controlled by adjusting the flow rate of each of the gases constituting the gas mixture by the gas flow control portion 150. The flow rate ratio of the gases introduced into the chamber 110 can be considered as the composition ratio of the gas mixture. Note that the composition ratio of the gases constituting the gas mixture, and other etching conditions may be changed in the course of etching.

Next, high-frequency power is applied to the upper electrodes 121 by the first high-frequency power supply 122, thereby generating a plasma in the chamber 110. The substrate 10 is exposed to the generated plasma, whereby plasma etching is performed. At the time of plasma etching, usually, a bias voltage is applied by the second high-frequency power supply 132. In this manner, the resist mask 12 and the compound semiconductor layer 11 are simultaneously etched. There is no particular limitation on the power that is input into the upper electrodes 121 and the bottom electrode (substrate stage 131), and suitable power may be selected. In an example, high-frequency power in the range of 400 W to 1000 W at 13.56 MHz is applied to the upper electrodes 121. By increasing the magnitude of the high-frequency power input into the upper electrodes 121, it is possible to increase the plasma density, so that a larger amount of an etchant (Cl radical in the case of Cl₂ and BCl₃) can be obtained, thus enabling high-speed etching. Increasing the bias voltage makes it possible to extract chlorine ions from the plasma, so that the etching rate can be increased, and the anisotropic etching properties can also be enhanced.

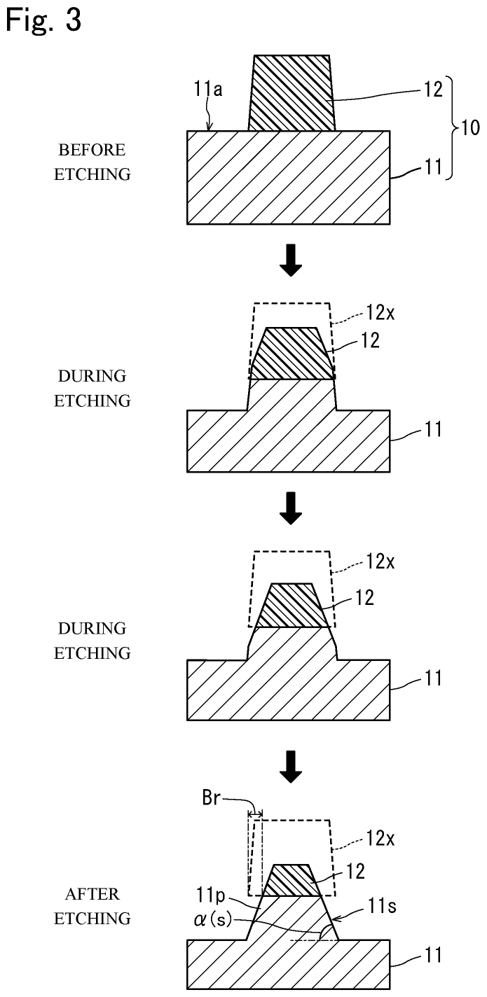

The shape that is formed on the compound semiconductor layer 11 by etching can be changed by changing the etching selectivity (Vs/Vr). FIGS. 3 to 5 schematically show an exemplary etching step when the etching selectivity Vs/Vr is changed. FIGS. 3 to 5 show, in a stepwise manner, the changes from the initial shape of the substrate 10 to the shape of the substrate 10 upon completion of etching. Note that the diagrams shown in FIGS. 3 to 5 are schematic diagrams for facilitating the understanding, and the shapes shown therein may be different from the actual shapes. In addition, the results shown in FIGS. 3 to 5 are results obtained when applying a bias voltage.

FIGS. 3 to 5 schematically show an example of the changes in the shape of the substrate 10 resulting from changes in the etching selectivity Vs/Vr. In FIGS. 3 to 5, as the plasma etching proceeds, the shape of the substrate 10 changes as indicated by the arrows. Note that the outer edge 12x of the initial resist mask 12 is indicated by dotted lines in FIGS. 3 to 5. In addition, FIGS. 3 to 5 show an example in which the resist mask 12 includes portions having a forward-tapered shape.

FIG. 3 schematically shows an example of the changes in the shape of the substrate 10 resulting from etching when the etching selectivity is Vs/Vr=1. As shown in FIG. 3, both the compound semiconductor layer 11 and the resist mask 12 are simultaneously etched by plasma etching. Consequently, a portion 11p having a forward-tapered shape is eventually formed on the compound semiconductor layer 11. FIG. 3 shows a retraction width Br of the resist mask 12.

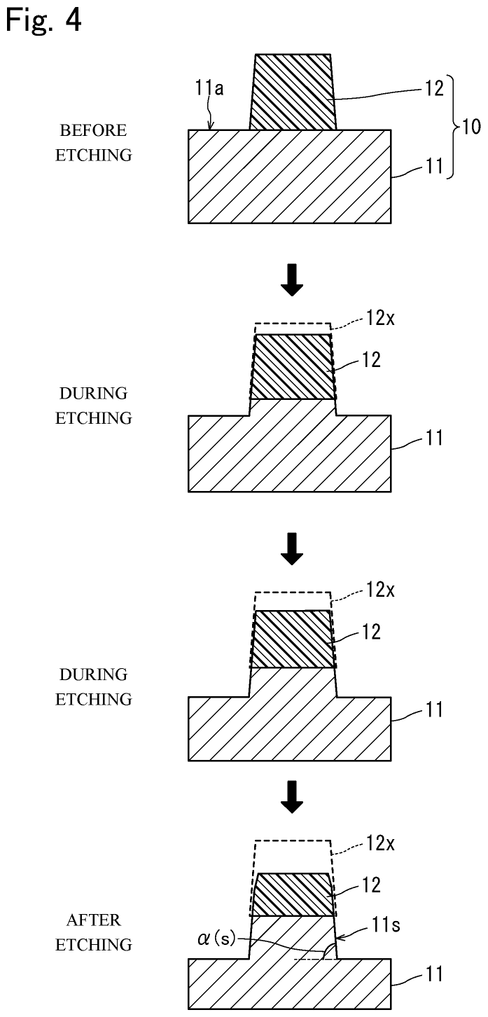

FIG. 4 schematically shows an example of the changes in the shape of the substrate 10 resulting from etching when the etching selectivity is Vs/Vr>1. As shown in FIG. 4, in the case of Vs/Vr>1, the angle of the gradient α(s) of the slope 11s is greater than that of the gradient α(s) shown in FIG. 3.

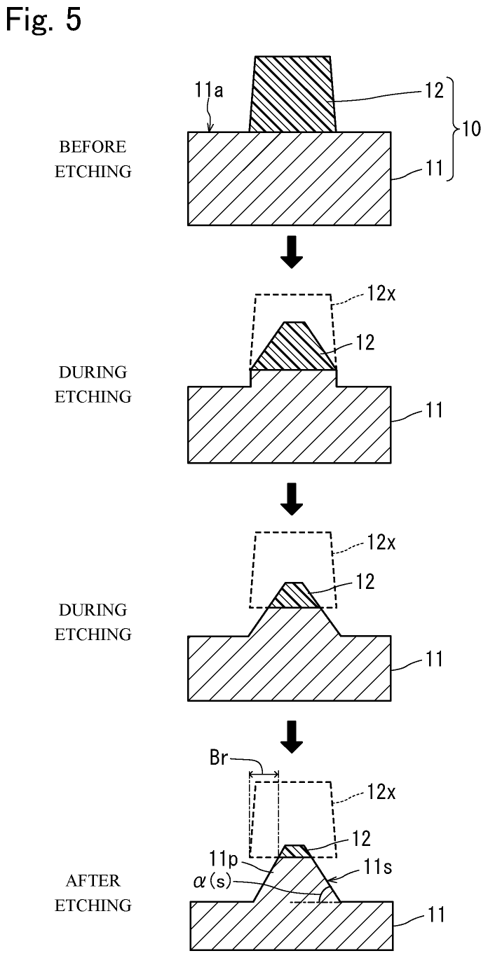

FIG. 5 schematically shows an example of the changes in the shape of the substrate 10 resulting from etching when the etching selectivity is Vs/Vr<1. In this case, the retraction width Br of the resist mask 12 is increased. As shown in FIG. 5, in the case of Vs/Vr<1, the angle of the gradient α(s) of the slope 11s is smaller than that of the gradient α(s) shown in FIG. 3.

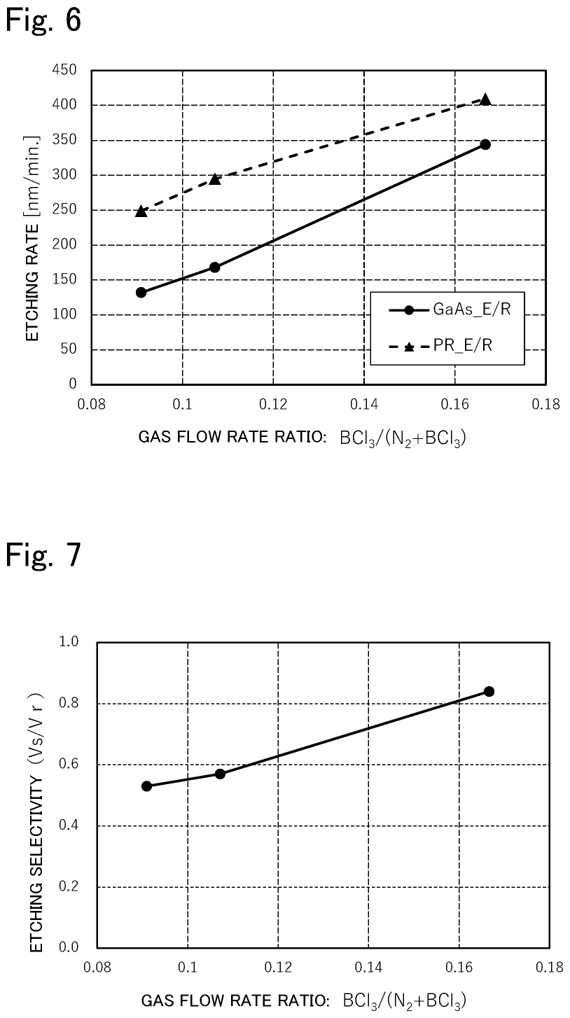

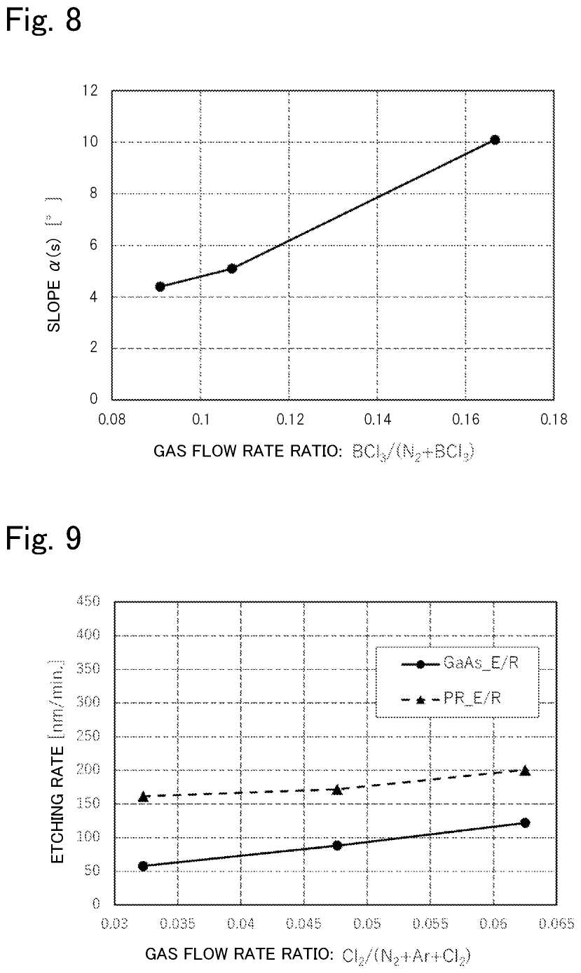

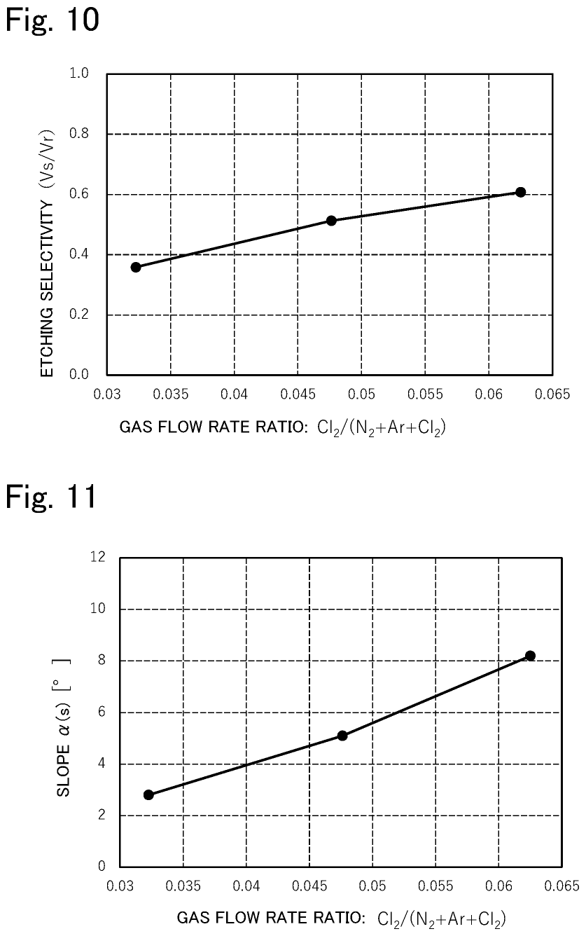

FIGS. 6 to 8 show the results of plasma etching in the case of using a gas mixture of BCl₃ gas and N₂ gas as the etching gas used for plasma etching. FIGS. 9 to 11 show the results of plasma etching in the case of using a gas mixture of Cl₂ gas, N₂ gas, and Ar gas as the etching gas used for plasma etching. FIGS. 6 to 11 show the results obtained when etching a GaAs substrate as the compound semiconductor layer 11. FIGS. 6 and 9 show a relationship between the etching rate Vs of the GaAs substrate and the gas flow rate ratio, and a relationship between the etching rate Vr of the resist mask 12 and the gas flow rate ratio, respectively. FIGS. 7 and 10 show a relationship between the etching selectivity (Vs/Vr) and the gas flow rate ratio. FIG. 8 and FIG. 11 each show a relationship between the gradient α(s) of the formed slope 11s and the gas flow rate ratio. Note that in the following drawings, “GaAs E/R” represents the etching rate of the GaAs substrate, and “PR_E/R” represents the etching rate of the resist mask 12.

The results shown in FIGS. 6 to 11 were obtained by using a resist mask 12 having an acute gradient α(r) of the side surface 12s. The plasma was generated by applying high-frequency power of 800 W at 13.56 MHz to the upper electrode. At the time of plasma etching, a bias voltage of 100 W was applied. In addition, the pressure in the chamber was 1.0 Pa.

As shown in FIGS. 7 and 10, the lower the proportion of the chlorine-containing gas, the smaller the etching selectivity was. In addition, the inclusion of the N₂ gas in the gas mixture made it possible to reduce the etching selectivity to less than 1. Consequently, as shown in FIGS. 8 and 11, it was possible to reduce the gradient α(s) of the slope 11s to 12° or less. To reduce the gradient α(s) of the slope 11s, the gradient α(r) of the side surface 12s of the resist mask 12 is preferably 45 degrees or less. To further reduce the gradient α(s), the gradient α(r) is preferably more acute.

The same etching as the etching shown in FIGS. 9 to 11 was performed except that N₂ gas was used in place of N₂ gas and Ar gas. That is, the same etching was performed using a gas mixture of Cl₂ gas and N₂ gas as the etching gas. Even when Ar gas was not added, similar results as those shown in FIGS. 9 to 11 were obtained as long as the flow rate ratio of the Cl₂ gas relative to the total flow rate of the gas mixture was the same.

On the other hand, when the gas mixture did not include N₂ gas, the etching selectivity had a larger value (e.g., 1 or more), resulting in an increase in the gradient α(s). The reason for this is not clear at present, but can be considered as follows. When the compound semiconductor layer (L) including Ga and As is plasma etched, As, which is relatively light-weight, is likely to be removed first. When the gas mixture does not include N₂ gas, Ga is likely to be removed, following the removal of As. On the other hand, when the gas mixture includes N₂ gas, Ga that is present in the compound semiconductor layer (L) and the nitrogen in the etching gas are considered to react with each other, to generate GaN and the like. As a result, there is the possibility that the etching rate Vs of the compound semiconductor layer (L) has been reduced. When the gas mixture includes N₂ gas, there is also the possibility that the etching rate Vr of the resist mask has been increased as a result of the resist mask and nitrogen reacting with each other.

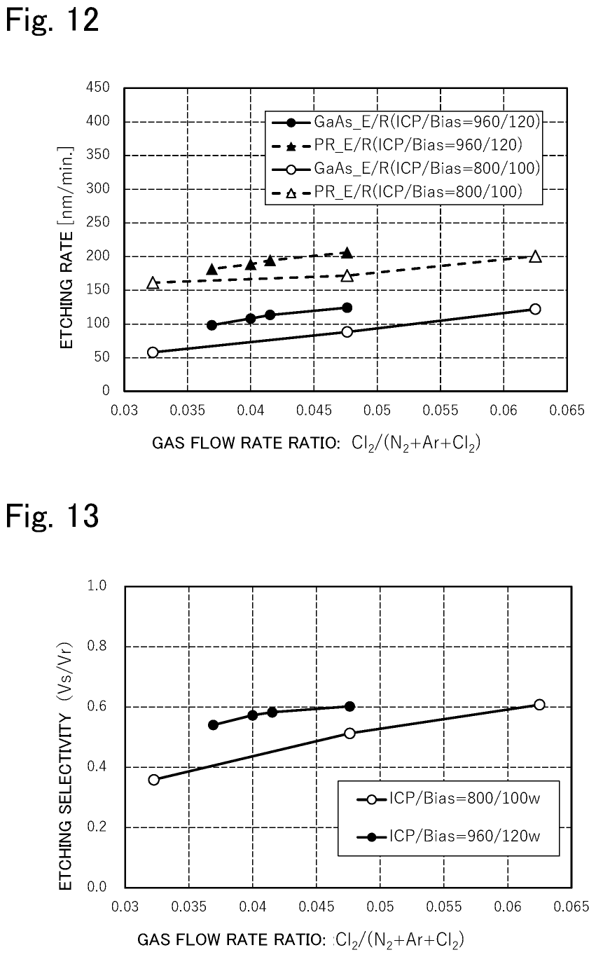

FIGS. 12 and 13 show the results obtained by etching the GaAs substrate by changing the high-frequency power applied to the upper electrodes 121 for generating the plasma, and the high-frequency power applied to the bottom electrode for applying a bias voltage. FIGS. 12 and 13 show the results obtained when the high-frequency power (ICP) applied to the upper electrodes 121 was 960 W, and the high-frequency power (Bias) applied to the bottom electrode was 120 W, and the results obtained when the high-frequency power (ICP) was 800 W, and the high-frequency power (Bias) was 100 W. As the etching gas used for plasma etching, a gas mixture of Cl₂ gas, N₂ gas, and Ar gas was used. FIG. 12 shows a relationship between the gas flow rate ratio and the etching rate. FIG. 13 shows a relationship between the gas flow rate ratio and the etching selectivity. When the high-frequency power (ICP) was 960 W and the high-frequency power (Bias) was 120 W, it was possible to increase the etching rate Vs while keeping the etching selectivity Vs/Vr low.

As a method for reducing the etching rate Vs of the compound semiconductor layer (L), it is conceivable to reduce the high-frequency power applied to the upper electrodes and the bottom electrode. However, in that case, there is the problem that the plasma becomes unstable. In addition, even if Vs/Vr can be reduced, there is the problem that the processing takes a long time because Vs is small, resulting in a reduction in productivity. According to the method of the present disclosure, it is possible to reduce the etching selectivity Vs/Vr under a condition where the plasma can be stably generated. Furthermore, according to the method of the present disclosure, it is possible to satisfy both a relatively high Vs (e.g., Vs>98 nm/min) and Vs/Vr<1, as shown in FIGS. 12 and 13, and it is therefore possible to improve the productivity.

The present disclosure is applicable to a plasma etching method and a production method for a semiconductor element.

### REFERENCE NUMERALS

10: Substrate
11: Compound semiconductor layer
11a: One principal surface
11s: Slope
12: Resist mask
12h: Opening
12s: Side surface
110: Chamber
Vr: Etching rate
Vs: Etching rate
α: Gradient

What is claimed is:

1. A plasma etching method for a compound semiconductor layer formed of a Group III-V compound semiconductor, comprising the steps of:
(i) placing, in a chamber, a substrate including the compound semiconductor layer and a resist mask that is disposed on one principal surface of the compound semiconductor layer and has an opening; and
(ii) plasma etching the compound semiconductor layer and the resist mask by exposing the compound semiconductor layer and the resist mask to a plasma in the chamber, thereby forming a slope that forms a forward-tapered shape on the compound semiconductor layer,
wherein the Group III-V compound semiconductor includes Ga and As, and
the plasma etching in the step (ii) is performed using, as an etching gas, a gas mixture including nitrogen gas and a gas containing chlorine.

2. The plasma etching method according to claim 1,
wherein the gas containing chlorine includes at least one gas selected from the group consisting of BCl₃ and Cl₂.

3. The plasma etching method according to claim 1,
wherein, in the step (ii), a volume ratio of the gases constituting the gas mixture is controlled such that a value of Vs/Vr, which is a ratio between an etching rate Vs of the compound semiconductor layer and an etching rate Vr of the resist mask, is less than 1.

4. The plasma etching method according to claim 1,
wherein a gradient of the slope formed on the compound semiconductor layer by the step (ii) is controlled by controlling a volume ratio of the gases constituting the gas mixture.

5. The plasma etching method according to claim 1,
wherein the gas mixture includes Ar gas.

6. A production method for a semiconductor element including a compound semiconductor layer formed of a Group III-V compound semiconductor, comprising the steps of:
(i) placing, in a chamber, a substrate including the compound semiconductor layer and a resist mask that is disposed on one principal surface of the compound semiconductor layer and has an opening; and
(ii) plasma etching the compound semiconductor layer and the resist mask by exposing the compound semiconductor layer and the resist mask to a plasma in the chamber, thereby forming a slope that forms a forward-tapered shape on the compound semiconductor layer,
wherein the Group III-V compound semiconductor includes Ga and As, and
the plasma etching in the step (ii) is performed using, as an etching gas, a gas mixture including nitrogen gas and a gas containing chlorine.

7. The production method for a semiconductor element according to claim 6,
wherein the gas containing chlorine includes at least one gas selected from the group consisting of BCl₃ and Cl₂.

8. The production method for a semiconductor element according to claim 6,
wherein, in the step (ii), a volume ratio of the gases constituting the gas mixture is controlled such that a value of Vs/Vr, which is a ratio between an etching rate Vs of the compound semiconductor layer and an etching rate Vr of the resist mask, is less than 1.

9. The production method for a semiconductor element according to claim 6,
wherein a gradient of the slope formed on the compound semiconductor layer by the step (ii) is controlled by controlling a volume ratio of the gases constituting the gas mixture.

10. The production method for a semiconductor element according to claim 6,
wherein the gas mixture includes Ar gas.
